(19) United States
(12) Patent Application Publication
(10) Pub. No.: US 2010/0102354 A1
(43) Pub. Date: Apr. 29, 2010

(54) LIGHT EMITTING DIODE PACKAGE

(75) Inventor: Chin-Yuan Hsu, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: EVERLIGHT ELECTRONICS CO., LTD., Taipei (TW)

(21) Appl. No.: 12/604,371

(22) Filed: Oct. 22, 2009

(30) Foreign Application Priority Data
Oct. 23, 2008 (TW) 97140696

(51) Int. Cl. H01L 33/00

(52) U.S. Cl. 257/99; 257/E33.066; 257/E33.062; 257/E33.059; 257/E33.058; 257/E33.057

(57) ABSTRACT

A light emitting diode (LED) package includes a circuit board and an LED chip. The circuit board has a top circuit layer and an insulating layer. The top circuit layer is disposed on the insulating layer, and the material of the insulating layer is selected from a group consisting of diamond, diamond like coating (DLC), AlN, BN, CrN and TiN. The LED chip is disposed on the circuit board and electrically connected with the top circuit layer of the circuit board. Since the material of the insulting layer is selected from materials with a high thermal conductivity, the heat dissipation performance and light-emitting efficiency of the LED package can be enhanced.

### CROSS-REFERENCE TO RELATED APPLICATION

This application claims the priority benefit of Taiwan application serial no. 97140696, filed Oct. 23, 2008. The entirety of the above-mentioned patent application is hereby incorporated by reference herein and made a part of specification.

### BACKGROUND OF THE INVENTION

1. Field of the Invention

The present invention generally relates to a light emitting diode (LED) package, in particular, to an LED package with desirable heat dissipation performance.

2. Description of Related Art

With the progress of semiconductor technology, the current LEDs have achieved a high-luminance output. Due to the advantages of saving power, a small volume, a low driving voltage, and being free of mercury, LEDs have been widely used in the displays and illumination fields. The luminance of the LEDs is relevant to a current input to the LEDs. Specifically, the greater the current input to the LEDs is, the higher the luminance of the LEDs is, and meanwhile, more heat energy is generated during the process of emitting light by the LEDs. If the heat energy is accumulated in the LEDs and is not dissipated in time, the operation temperature of the LEDs may be raised, thereby resulting in an overheating of the LEDs such that the luminance of the LEDs is reduced and the lifespan of the LEDs is shortened. In order to avoid the overheating problem, a high-power LED package must have a desirable heat dissipation performance to prevent the LEDs from being overheated.

Most of the current LED packages are fabricated by chip-on-board (COB) package technology. Generally, the COB package technology mainly includes the following process: directly adhering an LED chip on a circuit board; next, electrically connecting the LED chip to the circuit board through bonding wires by a wire-bonding process; and then, forming an encapsulant through a molding process to protect the LED chip and the bonding wires on the circuit board.

In the conventional LED packages, the heat dissipation performance of the circuit board has obvious impacts on the operation temperature of the LED chip. However, the conventional circuit boards mostly adopt silicon dioxide, alumina, or silicon nitride as an insulating layer, and the thermal conductivity coefficients of such insulating materials (silicon dioxide, alumina, or silicon nitride) are not high enough (between about 0.8 W/mK and 3.5 W/mK). Accordingly, the conventional LED packages need to be further improved in the heat dissipation performance.

### SUMMARY OF THE INVENTION

Accordingly, the present invention is directed to an LED package, which has desirable heat dissipation performance and light-emitting efficiency.

As embodied and broadly described herein, the present invention provides an LED package including a circuit board and an LED chip. The circuit board has a top circuit layer and an insulating layer. The top circuit layer is disposed on the insulating layer, and the material of the insulating layer is selected from a group consisting of diamond, diamond like coating (DLC), AlN, BN, CrN and TiN. Furthermore, the LED chip is disposed on the circuit board and electrically connected to the top circuit layer of the circuit board.

In an embodiment of the present invention, the circuit board includes a silicon substrate, a ceramic substrate, or a metal core substrate.

In an embodiment of the present invention, the ceramic substrate includes an alumina substrate or an AlN substrate.

In an embodiment of the present invention, the metal core substrate has a metal core layer, and the material of the metal core layer includes copper, copper-tungsten alloy, aluminum, or iron.

In an embodiment of the present invention, the top circuit layer includes a plurality of traces and a plurality of pads connected to the traces.

In an embodiment of the present invention, the LED chip has a front side, a rear side, and a plurality of electrodes disposed on the front side.

In an embodiment of the present invention, the LED package further includes a plurality of bonding wires, in which the rear side of the LED chip is bonded to the circuit board, and the bonding wires are connected between the electrodes and the top circuit layer.

In an embodiment of the present invention, the LED package further includes a plurality of bumps, in which the LED chip is flipped and disposed on the circuit board, and the electrodes of the LED chip are electrically connected to the top circuit layer via the bumps.

In an embodiment of the present invention, the LED chip has a front side, a rear side, a first electrode disposed on the front side, and a second electrode disposed on the rear side.

In an embodiment of the present invention, the LED package further includes a bonding wire, in which the second electrode disposed on the rear side is bonded to the circuit board, and the first electrode disposed on the front side is electrically connected to the top circuit layer through the bonding wire.

In an embodiment of the present invention, a thermal conductivity coefficient of the insulating layer is between 12 W/mK and 1000 W/mK.

In an embodiment of the present invention, a thickness of the insulating layer is between 500 nm and 5000 nm.

In an embodiment of the present invention, the LED package further includes an encapsulant, and the encapsulant is disposed on the circuit board to encapsulate the LED chip.

As the present invention adopts the material with a high thermal conductivity coefficient as the insulating layer in the circuit board, the LED package of the present invention has desirable heat dissipation performance and light-emitting efficiency.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of an LED package according to an embodiment of the present invention.

FIG. 2 is a schematic cross-sectional view of an LED package according to another embodiment of the present invention.

FIG. 3 is a schematic cross-sectional view of an LED package according to yet another embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

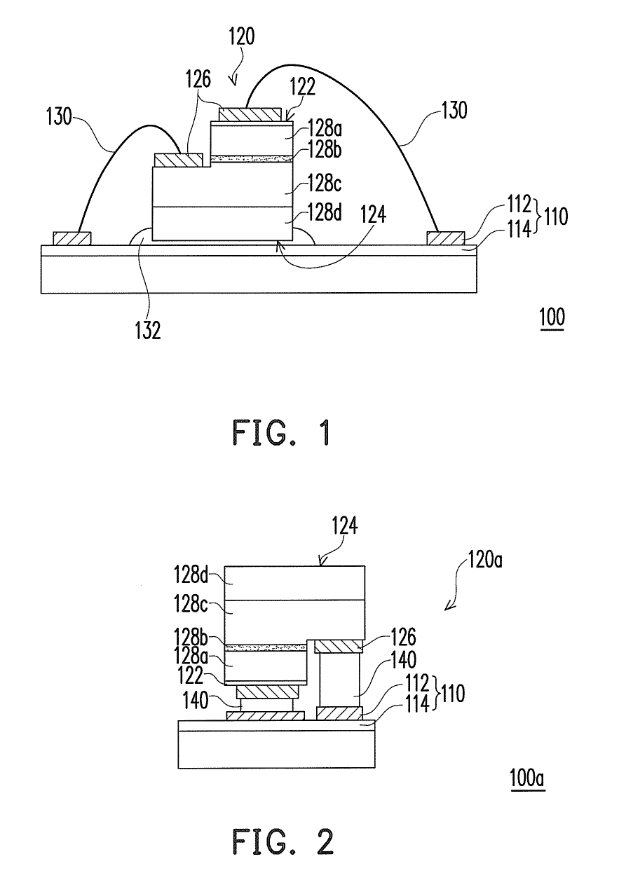

FIG. 1 is a schematic cross-sectional view of an LED package according to an embodiment of the present invention. Referring to FIG. 1, an LED package 100 of this embodiment includes a circuit board 110 and an LED chip 120. The circuit board 110 has a top circuit layer 112 and an insulating layer 114. The top circuit layer 112 is disposed on the insulating layer 114, and the material of the insulating layer 114 is selected from a group consisting of diamond, DLC, MN, BN, CrN and TiN. The LED chip 120 is disposed on the circuit board 110 and is electrically connected to the top circuit layer 112 of the circuit board 110. The circuit board 110 may be a silicon substrate, a ceramic substrate, or a metal core substrate. The ceramic substrate includes alumina substrate or AlN substrate. The metal core substrate has a metal core layer, and the material of the metal core layer includes copper, copper-tungsten alloy, aluminum, or iron. The top circuit layer 112 includes a plurality of traces and a plurality of pads connected to the traces (both the traces and the pads are not shown). Furthermore, the thermal conductivity coefficient of the insulating layer 114 is between 12 W/mK and 1000 W/mK, and the thickness of the insulating layer 114 is between 500 nm and 5000 nm.

The LED chip 120 has a front side 122, a rear side 124, and a plurality of electrodes 126 disposed on the front side 122. Specifically, the LED chip 120 includes a P-type semiconductor layer 128a, a multi-quantum well (MQW) light-emitting layer 128b, an N-type semiconductor layer 128c, and a base material 128d. The N-type semiconductor layer 128c is disposed on the base material 128d. The MQW light-emitting layer 128b is disposed on a part of the region of the N-type semiconductor layer 128c. The P-type semiconductor layer 128a is disposed on the MQW light-emitting layer 128b. Particularly, the electrodes 126 on the left side are electrically connected to the N-type semiconductor layer 128c that is not covered by the MQW light-emitting layer 128b, and the electrodes 126 on the right side are electrically connected to the P-type semiconductor layer 128a. The P-type semiconductor layer 128a and the N-type semiconductor layer 128c are both semiconductor epitaxial layers of compounds formed by Group III-V elements. The MQW light-emitting layer 128b is also called an active layer, and when a forward bias is applied between the electrodes 126, the MQW light-emitting layer 128b emits light. The LED package 100 further includes a plurality of bonding wires 130. The rear side 124 of the LED chip 120 is bonded to the circuit board 110 through a conductive adhesive 132, and the bonding wires 130 are electrically connected to the electrodes 126 and the top circuit layer 112.

Table 1 shows dielectric constants and thermal conductivity coefficients of the materials of the insulating layer according to an embodiment of the present invention. Referring to Table 1, the materials of this embodiment selected from a group consisting of diamond, DLC, MN, BN, CrN and TiN have thermal conductivity coefficients higher than that of the conventional materials, so that the heat energy generated during the photoelectric conversion can be successfully dissipated to the exterior by the insulating layer 114 in this embodiment, instead of being accumulated in the LED package 100. The LED package 100 of this embodiment can successfully dissipate the generated heat energy to the exterior by the insulating layer 114, even if the LED package 100 is continuously used for a long time. Therefore, the decrement of the light-emitting efficiency due to being influenced by the heat energy is greatly reduced, thereby maintaining a long-time stable light-emitting efficiency.

TABLE 1

| | Thermal Conductivity | |
|---|---|---|
| Material of Insulating Layer | Coefficient (W/mK) | Dielectric Constant |
| Diamond | 1000 | 6.0 |
| DLC | 500-600 | 3.5-5.7 |
| AlN | 170-230 | 9.0 |
| BN | 20 | 4.0 |
| CrN | 12 | 4.5 |
| TiN | 19 | 5.6 |

FIG. 2 is a schematic cross-sectional view of an LED package according to another embodiment of the present invention. Referring to FIG. 2, an LED package 100a of this embodiment includes a circuit board 110 and an LED chip 120a. The structures of the circuit board 110 and the LED chip 120a are substantially the same as that of the above embodiment and will not be described herein repeatedly.

As shown in FIG. 2, the LED package 100a further includes a plurality of bumps 140. The LED chip 120a is flipped and disposed on the circuit board 110, and the electrodes 126 of the LED chip 120a are electrically connected to the top circuit layer 112 via the bumps 140. As the LED chip 120a is flipped and disposed on the circuit board 110, the signal-transmission path between the LED chip 120a and the circuit board 110 can be shortened significantly. Furthermore, the bumps 140 not only can reduce the sheet resistance, but also can reduce the thermal resistance between the LED chip 120a and the circuit board 110, such that the heat energy is efficiently conducted to the insulating layer 114. Therefore, the insulating layer 114 can achieve the heat dissipation function efficiently, and thus the LED package 100a has desirable thermal conductivity. The architecture of LED package can be applied to LEDs, high-power LEDs, ultra-high-power LEDs, and laser diodes.

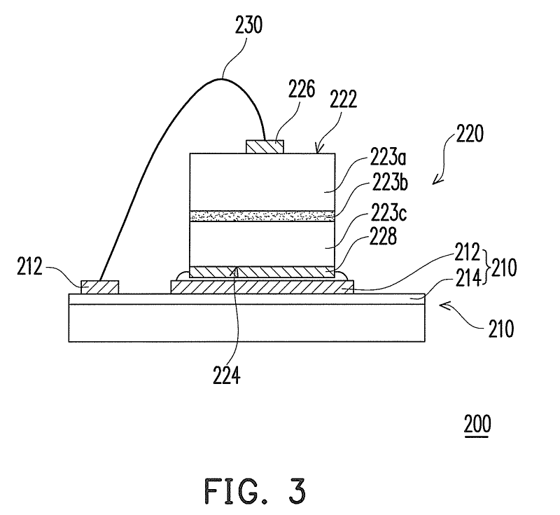

FIG. 3 is a schematic cross-sectional view of an LED package according to yet another embodiment of the present invention. Referring to FIG. 3, an LED package 200 includes a circuit board 210 and an LED chip 220. The circuit board 210 has a top circuit layer 212 and an insulating layer 214. The top circuit layer 212 is disposed on the insulating layer 214, and the material of the insulating layer 214 is selected from a group consisting of diamond, DLC, MN, BN, CrN and TiN. The dielectric constants and thermal conductivity coefficients of the materials of the insulating layer can be obtained from Table 1.

The LED chip 220 is disposed on the circuit board 210 and is electrically connected to the top circuit layer 212 of the circuit board 210. The top circuit layer 212 includes a plurality of traces and a plurality of pads connected to the traces (both the traces and the pads are not shown). The LED chip 220 has a front side 222, a rear side 224, a first electrode 226 disposed on the front side 222, and a second electrode 228 disposed on the rear side 224. The LED chip 220 includes a P-type semiconductor layer 223a, a MQW light-emitting layer 223b, and an N-type semiconductor layer 223c. The N-type semiconductor layer 223c is disposed on the top circuit layer 212. The MQW light-emitting layer 223b is disposed on the N-type semiconductor layer 223c. The P-type semiconductor layer 223a is disposed on the MQW light-emitting layer 223b. A second electrode 228 is disposed between the N-type semiconductor layer 223c and the top circuit layer 212 and is electrically connected to the N-type semiconductor layer 223c and the top circuit layer 212. The LED package 200 further includes a bonding wire 230. The material of the second electrode 228 on the rear side 224 of the LED chip 220 is, for example, gold, tin, or gold-tin alloy, and the material of the top circuit layer 212 on the circuit board 210 may be selected as gold or silver. When the temperature is raised to a temperature for the eutectic reaction, the eutectic bonding occurs to the second electrode 228 and the top circuit layer 212. The first electrode 226 disposed on the front side 222 of the LED chip 220 is electrically connected to the top circuit layer 212 through the bonding wire 230.

In view of the above, as the LED package of the present invention adopts an insulating layer with a high thermal conductivity coefficient, the heat energy generated during the process of emitting lights by the LED chip can be successfully dissipated out of the LED package, such that the LED package has a stable light-emitting efficiency and a long lifespan.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting diode (LED) package, comprising:
a circuit board comprising a top circuit layer and an insulating layer, wherein the top circuit layer is disposed on the insulating layer, and a material of the insulating layer is selected from a group consisting of diamond, diamond like coating (DLC), AlN, BN, CrN and TiN; and
an LED chip disposed on the circuit board and electrically connected to the top circuit layer of the circuit board.

2. The LED package according to claim 1, wherein the circuit board comprises a silicon substrate, a ceramic substrate, or a metal core substrate.

3. The LED package according to claim 2, wherein the ceramic substrate comprises an alumina substrate or an AlN substrate.

4. The LED package according to claim 2, wherein the metal core substrate comprises a metal core layer, and a material of the metal core layer comprises copper, copper-tungsten alloy, aluminum, or iron.

5. The LED package according to claim 1, wherein the top circuit layer comprises a plurality of traces and a plurality of pads connected to the traces.

6. The LED package according to claim 1, wherein the LED chip comprises a front side, a rear side, and a plurality of electrodes disposed on the front side.

7. The LED package according to claim 6, further comprising a plurality of bonding wires, wherein the rear side of the LED chip is bonded to the circuit board, and the bonding wires are connected between the electrodes and the top circuit layer.

8. The LED package according to claim 6, further comprising a plurality of bumps, wherein the LED chip is flipped and disposed on the circuit board, and the electrodes of the LED chip are electrically connected to the top circuit layer via the bumps.

9. The LED package according to claim 1, wherein the LED chip comprises a front side, a rear side, a first electrode disposed on the front side, and a second electrode disposed on the rear side.

10. The LED package according to claim 9, further comprising a bonding wire, wherein the second electrode disposed on the rear side is bonded to the circuit board, and the first electrode disposed on the front side is electrically connected to the top circuit layer through the bonding wire.

11. The LED package according to claim 1, wherein a thermal conductivity coefficient of the insulating layer is between 12 W/mK and 1000 W/mK.

12. The LED package according to claim 1, wherein a thickness of the insulating layer is between 500 nm and 5000 nm.

13. The LED package according to claim 1, further comprising an encapsulant disposed on the circuit board to encapsulate the LED chip.
